(19) United States
(12) Patent Application Publication
(10) Pub. No.: US 2025/0348639 A1
(43) Pub. Date: Nov. 13, 2025

(54) OPTIMIZATION TARGETS TO REDUCE INSTABILITY TRANSPORT IN MAGNETICALLY CONFINED PLASMAS

(71) Applicant: ExoFusion Inc., Bellevue, WA (US)

(72) Inventors: Michael T. Kotschenruether, Leander, TX (US); Xing Liu, Leander, TX (US)

(73) Assignee: ExoFusion Inc., Bellevue, WA (US)

(21) Appl. No.: 19/201,856

(22) Filed: May 7, 2025

Related U.S. Application Data
(60) Provisional application No. 63/643,901, filed on May 7, 2024.

(51) Int. Cl. G06F 30/28; G06F 30/27

(52) U.S. Cl. CPC G06F 30/28; G06F 30/27

(57) ABSTRACT

A computer-implemented method is disclosed for designing magnetic field geometries in magnetically confined plasmas, such as stellarators, to minimize energy or particle transport due to plasma turbulence. The method utilizes machine learning (ML) models trained on datasets of gyrokinetic simulations. These models predict turbulent transport based on geometric features derived from the magnetic configuration, which influence solutions of the gyrokinetic equation in ballooning representation. The input features include both raw geometrical quantities-such as field strength, curvature drifts, and perpendicular wavenumbers-and engineered features derived therefrom. The models may incorporate translational invariance and be implemented as convolutional neural networks or via solutions to parameterized differential equations. The resulting ML-driven target functions are computationally efficient and suitable for use in optimization algorithms to identify magnetic geometries that enhance plasma confinement.

### CROSS-REFERENCE TO RELATED APPLICATIONS

This application claims priority to U.S. provisional application Ser. No. 63/643,901, filed on May 7, 2024, which is incorporated herein by reference in its entirety.

### FIELD OF INVENTION

This invention generally relates to devices to confine magnetically confined plasmas, including for nuclear fusion applications. Also, machine learning and optimization of such devices. The present invention is directed to improvements in the design and operation of magnetic confinement devices for plasma containment, such as stellarators, by employing computational techniques that enhance the efficiency and accuracy of magnetic field geometry optimization.

### TECHNICAL FIELD AND PROBLEM CONTEXT

The present invention is directed to improvements in the design and operation of magnetic confinement devices for plasma containment, such as stellarators, by employing computational techniques that enhance the efficiency and accuracy of magnetic field geometry optimization.

### BACKGROUND OF THE INVENTION

Within the art of confining plasmas in magnetic fields, complex magnetic field configurations are usually used. The design process for these devices uses intricate algorithms to arrive at these configurations. These algorithms strive to optimize performance of the confined plasma, which depends sensitively on the magnetic configuration. There are many names for various types of such magnetic configurations, but for simplicity, we will refer to all magnetic configurations to confine plasmas as stellarators. This terminology is intended to include, but not be limited to, magnetic configurations that have a substantial degree of symmetry, such as axi-symmetry (as in tokamaks), quasi axi-symmetry, quasi helical symmetry, or other symmetries. These geometries often have a significant three-dimensional character. It is well known that there are a very large number of parameters that characterize stellarator magnetic field geometry. Or equivalently, a very large number of parameters can characterize the magnetic means that produce the magnetic field, which can include coils with current, permanent magnets, ferromagnetic materials, and other means. (For the purposes of this disclosure, when we say optimization of the magnetic field, we take this to also include optimization of the means to create the magnetic field.) Algorithms must search through this very large parameter space in order to design a device that achieves optimal performance. This search is performed by computer codes that implement computational optimization algorithms. We will refer to such algorithms and codes as Optimization Algorithms (OA). Today's stellarator devices are designed using such OA before they are constructed.

The quality of these algorithms determines, in large measure, the performance of the actual constructed device. Good performance of the OA is thus crucial to good performance of the constructed stellarator.

In the usual terminology, the properties of the stellarator to be optimized are included in the so-called objective function or cost function of the OA. The objective function usually includes multiple desired properties. These are often quite disparate, and many are well known in the art. These properties may include, but are not limited to, magnetic coil cost or coil complexity, plasma transport from neoclassical processes, plasma pressure limitations from MagnetoHydroDynamic (MHD) instabilities, and plasma transport due to instabilities. There must be a mathematical description or target for each of these particular desired properties. The quality of the target determines, in substantial measure, the degree to which the desired property will be present in actuality. We will use the term target or target function to mean the sub-component of the total objective function which describes a particular property. The target for each desired property is unique to that property.

This disclosure relates to targets to optimize transport from instabilities of plasmas in stellarator magnetic configurations, to enable the design of a stellarator with high confinement. High confinement is widely recognized as a major advantage of a device to magnetically confine plasma, especially for applications in nuclear fusion. And transport from instabilities is usually the largest contributor to degradation of confinement, so it is highly desirable to reduce it or optimize it.

It is well known that magnetic field geometry affects plasma transport. Low transport is synonymous with high confinement, so is widely understood as being necessary to attain energy gain from nuclear fusion. It is also widely understood that plasma transport arises from two sources 1) plasma instabilities and 2) neoclassical transport. The former transport often dominates, especially when neoclassical transport is reduced in optimized stellarator magnetic configurations.

Hence, the reduction of instability transport becomes a key issue in the optimization of stellarator designs. A good target for this is therefore needed. The dynamics of plasma instabilities that cause transport are described by the so-called gyrokinetic equation (which is well known in the art), so we will call them gyrokinetic instabilities. We will use the term gyrokinetic transport for the transport resulting from those instabilities.

The present disclosure relates to mathematical targets to optimize gyrokinetic transport from gyrokinetic instabilities. Within the art there are various targets that have been devised and used with OA to design stellarator magnetic geometry with a goal of reducing gyrokinetic transport. This disclosure reveals advantageous novel targets for that purpose.

This is an example of a target for a property other than transport: to maximize the amount of pressure that a stellarator can contain before violent Magneto-Hydro-Dynamic (MHD) instabilities arise. OA often use targets based upon ideal MHD stability calculations for this. These often include consideration of a sub-class of MHD instabilities known as “ballooning modes”. It is well known to those in the art that these are described mathematically in what is known as the ballooning representation.

Different targets from MHD are needed for low transport from plasma instabilities. The dominant gyrokinetic instabilities causing transport are usually the Ion Temperature Gradient instabilities (ITG) and Trapped Electron Modes (TEM). These instabilities are coupled together, and we refer to this composite mode as the ITG/TEM. Optimization of transport from ITG/TEM is important, but other instabilities can also be important. Kinetic Ballooning Modes (KBM) can also give strong transport, as can other gyrokinetic instabilities, including so-called Universal Modes and Micro Tearing Modes. All these instabilities (aka “modes of oscillation”, or “modes” for short) can be described by gyrokinetic equations. It is also well known that such modes are often described in various ballooning representations for the gyrokinetic equation. In fact, within the art, the ballooning representation is the most common way to use the gyrokinetic equation for purposes of predicting transport of magnetic geometries.

The use of simulations to find solutions of the gyrokinetic equation (usually in the ballooning approximation) has proven to give a good prediction of the transport properties of magnetically confined plasmas. Such simulations could, in principle, be used directly in the target to reduce instability transport in an OA. But such simulations are extremely computationally expensive, so this is usually not a practical approach: it would take far too much time or computational resources to thoroughly explore the very large search space of the magnetic field (or magnetic means to create it) to arrive at an optimum configuration. It is important to formulate targets that can be evaluated efficiently, that is, without excessive computational time or other computational resources.

So, what is desired is a predictive model of gyrokinetic transport properties that is adequately accurate, and much more efficient to implement as a target for OA. As is well known in the art, such a predictive model could be obtained by starting with a large dataset of gyrokinetic simulation results and using supervised learning to train a surrogate model for the property of interest. Such models are often referred to as Machine Learning (ML) models. Such ML models are usually enormously faster than gyrokinetic simulations.

As is well known in the art of developing ML models, selection of the features used as input is often one of the most critical aspects of obtaining good predictive performance. We now describe desirable features that encapsulate the way that magnetic geometry enters into the gyrokinetic equation. These are, therefore, desirable features for predictive models for gyrokinetic properties that are used in OA for the purpose of designing an optimized magnetic geometry with high confinement.

Targets that make use of the following could be very advantageous, since this would result in improved confinement performance of stellarator devices that are constructed based upon the magnetic fields designed by OA that use these targets.

To reiterate this point in somewhat more detail: gyrokinetic ITG/TEM and other instabilities are usually described in the ballooning representation (related to the approximation used for MHD ballooning modes) of a gyrokinetic equation. Many of the geometrical quantities that enter the gyrokinetic ballooning equation are similar to geometrical quantities that enter the MHD ballooning equation. Optimization of magnetic geometry for gyrokinetic instability transport comes down to optimizing these geometrical quantities, or, in a more complete phrasing: optimizing solutions of the gyrokinetic equation by finding optimal values of these geometrical quantities that in turn lead to solutions of the gyrokinetic with optimal transport. And to achieve this in a practical way, it would be highly advantageous to have an efficient ML model of the gyrokinetic transport that arises in a given geometry. This could then be used in an OA to design advantageous magnetic field geometries.

The quantities whereby the magnetic geometry enters the gyrokinetic equation (in the ballooning representation) are as follows. Before delineating these, we briefly describe the ballooning representation as background.

The following details of the ballooning representation are generally known in the art. It is not of essence for this invention how this is done. The computation of these quantities is already performed by means that are known in the art. Rather, the essence of this invention is to develop ML models of the solutions of the gyrokinetic equation after this is done. This description is included here merely as background.

A perpendicular wavenumber [symbol] is associated with the fluctuations, as a function of position along the equilibrium magnetic field line. That position is parameterized by a coordinate θ, which is often an angle, so [symbol] (θ). (Other coordinates could be used as well without a significant effect upon the results, such as the length along a field line [symbol] ) This wavenumber is perpendicular to the equilibrium magnetic field [symbol] (the dot product [symbol] (θ)· [symbol] =0). The geometric functions that enter the gyrokinetic equation are:
1) The field line curvature driving term which we will denote by ω_{κ}. It is related to the curvature drift velocity vax by [symbol] by ω_{κ}(θ)= [symbol] · [symbol] . It is well known to those skilled in the art that stellarators have some regions of “bad” curvature and this engenders plasma instabilities leading to transport, including ITG/TEM, KBM, and others. So ω_{κ} is a function of θ: ω_{κ}(θ).

A similar quantity enters which gives the effect of drifts in the gradient of the magnetic field [symbol] , ω_{B}(θ)= [symbol] · [symbol] .
2) The magnitude of the perpendicular wavenumber k_{⊥}=| [symbol] |. This is also a function of θ: k_{⊥}(θ).
3) The Jacobian of the coordinate transformation that relates the parallel coordinate θ to position along a field line. This can equivalently be described as the differential distance along a field line [symbol] , d [symbol] /dθ= [symbol] (θ). Sometimes the Jacobian is defined as the inverse of this, perhaps with other normalizations like the magnetic field. These differences in the specific definition used by various workers in the field are immaterial to this patent, and are well understood by those skilled in the art. The essence of this function is that it describes the differential distance along a field line, or its inverse, with some normalization.
4) The total magnetic field strength along a field line B(θ). This quantity plays a central role in trapped particle dynamics. As is well known in the art, particles can be trapped in wells of the magnetic field (regions of low B strength), and these particles can have a special impact upon the instabilities.

Instabilities that are local to a given field line can be computed, using the gyrokinetic equation, using the quantities above to specify the way that magnetic geometry enters the gyrokinetic equation. Hence, for an ML model, the quantities ω_{κ}(θ), ω_{B}(θ), k_{⊥}(θ), [symbol] (θ) and B(θ) are a complete set of input features for the gyrokinetic equation. They are thus good features for a target function to optimize instability transport on a particular field line of a magnetic geometry.

As is often done in the art for a function of a variable, these functions are approximated by vectors of their values at discrete positions of the variable θ, or described by some other discrete basis set. We will refer to the functions above as the geometrical features.

For conciseness going forward, we will replace the set (or any subset) of the geometric features ω_{κ}(θ), k_{⊥}(θ), [symbol] (θ), B(θ), ω_{B}(θ), by the single symbol X.
I.e, X⊆{ω_{κ}(θ), k_{⊥}(θ), [symbol] (θ), B(θ), ω_{B}(θ)}

We will refer to these as the raw features. To summarize, it is well known that the quantities in X are the way that geometry enters the gyrokinetic equation. Hence these are the geometrical features used to calculate or estimate the turbulent transport in the vicinity of that field line.

The gyrokinetic equation also has dependencies on plasma parameters that are independent of θ. These too are well known in the art. Examples include the plasma density and temperature, collision frequency, spatial gradients of density and temperature (in ballooning representation), etc. These are sometimes referred to as local scalar parameters (since they are independent of θ), and we will refer to them as such. We will denote any set of such local scaler parameters by S.

### Technical Improvement Statement

The invention provides a technical improvement over prior plasma optimization techniques by reducing computational time and increasing accuracy of magnetic geometry optimization through surrogate models based on machine learning. This enables practical exploration of high-dimensional parameter spaces that would otherwise be infeasible using direct simulation.

### Industrial Applicability

The present invention is industrially applicable to the design and development of magnetic confinement systems used in plasma physics, particularly for controlled thermonuclear fusion. Magnetic confinement fusion devices, such as stellarators and tokamaks, rely on carefully engineered magnetic field geometries to confine high-temperature plasmas and achieve energy-producing reactions. The invention provides methods and systems that are capable of improving the efficiency and performance of such devices through data-driven optimization of magnetic field configurations.

In particular, the computer-implemented methods described herein enable the use of surrogate machine learning models to predict turbulent transport properties in magnetically confined plasmas. These predictions are used as part of an optimization process to design magnetic field geometries with improved confinement characteristics. The invention reduces the computational burden associated with direct gyrokinetic simulations and allows researchers and engineers to explore large design spaces more effectively.

This invention is applicable to industrial sectors involved in the research, prototyping, and development of fusion energy systems, including but not limited to government research laboratories, private-sector fusion companies, and academic institutions. The invention may also be applied to related industrial uses where plasma confinement and control are required, including plasma-based material processing, particle accelerators, and advanced space propulsion systems.

The invention may be implemented using standard computing hardware and software infrastructure, including high-performance computing clusters or cloud-based systems, and is compatible with common data processing frameworks. As such, it is readily adoptable within existing workflows used in plasma physics simulation and reactor design.

Accordingly, the invention provides a practical, scalable, and technically grounded solution for enhancing the design of fusion devices, thereby contributing to the industrial realization of clean and sustainable energy production through nuclear fusion.

### SUMMARY OF THE INVENTION

The present invention relates to systems and computer-implemented methods for the design and optimization of magnetic field geometries in magnetically confined plasma devices, such as stellarators, with the goal of improving plasma confinement by reducing transport losses due to turbulence. In particular, the invention provides efficient computational techniques for estimating turbulent transport using surrogate machine learning (ML) models trained on results from gyrokinetic simulations.

In one aspect, the invention provides a computer-implemented method for designing magnetic geometries that optimize confinement by reducing energy and particle transport driven by microinstabilities. The method comprises generating a set of raw geometric features that influence gyrokinetic transport, constructing engineered features derived therefrom, and applying a trained ML model to estimate turbulent transport. The model output is used within an optimization algorithm to iteratively refine the magnetic configuration. The invention is particularly applicable to the design of stellarators, but may be extended to other types of magnetic confinement systems.

In another aspect, the ML models employed in the invention are trained using supervised learning to reproduce results of gyrokinetic simulations. These models may be implemented as convolutional neural networks (CNNs), functional operators, or systems of differential equations that reflect known physical invariances such as translational symmetry. The use of such surrogate models significantly reduces computational cost while preserving accuracy in predicting transport behavior. The surrogate models may be one-dimensional or two-dimensional, depending on whether the geometric input features vary along one or more coordinates on a magnetic flux surface.

The invention also discloses novel objective functions, or target functions, which are used to guide the optimization of magnetic configurations. These targets may be expressed as integrals, maxima, or solutions to integro-differential or partial differential equations involving the geometric features. In one embodiment, the invention enables the engineering of magnetic configurations that exhibit strong density gradient stabilization (DGS), a transport-reducing mechanism. Such configurations offer improved performance in confinement and are particularly valuable for the development of economically viable fusion reactors.

In certain embodiments, the ML models used to predict transport include non-adiabatic electron dynamics and are trained using simulation data that more accurately reflects the behavior of realistic plasmas. These models may be evaluated rapidly and can be embedded within computer-implemented optimization algorithms executed on classical computing hardware.

Accordingly, the present invention provides a technical solution to the problem of computationally intractable optimization of plasma-confining magnetic geometries, by introducing an efficient and physically grounded framework that enables practical design of high-performance fusion devices. The invention is applicable across jurisdictions and supports international development of magnetic confinement technologies for clean energy production.

The systems and methods disclosed herein are implemented using one or more processors, memory, and storage devices capable of executing software instructions, including trained machine learning models. The models are trained using datasets derived from simulations of gyrokinetic transport in plasma configurations, and executed to evaluate objective functions in optimization algorithms. The computer-implemented methods disclosed herein effectuate the design of a physical device—specifically, the magnetic confinement system—by outputting optimized magnetic field parameters that reduce turbulent transport, thereby enhancing plasma confinement performance in a manner not achievable through manual design or traditional simulation alone.

The invention integrates domain-specific scientific and engineering knowledge (plasma physics and magnetic geometry) with computational modeling techniques (machine learning) in a non-generic manner that constitutes significantly more than a mere implementation of an abstract idea on a computer.

The present invention provides computer-implemented methods for designing magnetic field geometries in magnetically confined plasma devices, such as stellarators, to minimize energy and particle losses due to turbulence. More specifically, the invention introduces machine learning (ML)-based surrogate models that approximate the transport behavior resulting from gyrokinetic instabilities, using inputs derived from magnetic geometry. These models are incorporated into optimization algorithms to enable the efficient design of magnetic field configurations with superior confinement properties.

The invention addresses the significant computational challenge associated with directly simulating gyrokinetic transport across a large configuration space. By replacing expensive direct simulations with fast surrogate ML models trained on a subset of such simulations, the invention enables practical exploration of magnetic design spaces to identify configurations with favorable confinement performance. The surrogate models use as inputs a set of geometric features, which describe how magnetic geometry enters the gyrokinetic equation in ballooning representation. These features may include magnetic field strength, curvature drift frequency, grad-B drift frequency, perpendicular wavenumber, and field line Jacobian.

The machine learning models used in the invention may include neural networks, such as convolutional neural networks (CNNs), and may also be formulated as parameterized integral or differential operators. The models incorporate desirable physical properties such as translational invariance, and may be trained using gyrokinetic simulation data that includes non-adiabatic electron dynamics to capture complex instability behavior.

The invention also introduces a novel set of target functions for use in optimization algorithms that design stellarator configurations. These target functions are computed using the surrogate ML models and can include functionals of the predicted transport properties, engineered to preserve physical invariances and reduce model dimensionality. Example target functions include integrals, maxima, and solutions to integro-differential equations involving geometric features, all designed to guide the optimization process toward magnetic field geometries that exhibit low turbulent transport.

In one embodiment, the invention enables the optimization of magnetic geometries to enhance a specific transport-reducing mechanism known as density gradient stabilization (DGS), which suppresses instabilities by decoupling turbulent fluctuations from trapped electrons. The invention provides methods for quantifying this property and incorporating it into the optimization process through appropriately constructed target functions and surrogate models. By combining machine learning, gyrokinetic physics, and optimization techniques, the invention enables the practical and efficient design of next-generation magnetic confinement devices with enhanced plasma performance, advancing the field of controlled nuclear fusion.

### BRIEF DESCRIPTION OF THE DRAWINGS

FIG. 1 illustrates one embodiment of a computer implemented method for designing a magnetic field geometry of a confined plasma to optimize the losses of energy or particles from plasma turbulence.

FIG. 2 illustrates another embodiment of a computer-implemented method of designing a magnetic field geometry of a magnetically confined plasma for optimizing the losses of energy or particles from plasma turbulence.

### DETAILED DESCRIPTION OF THE INVENTION

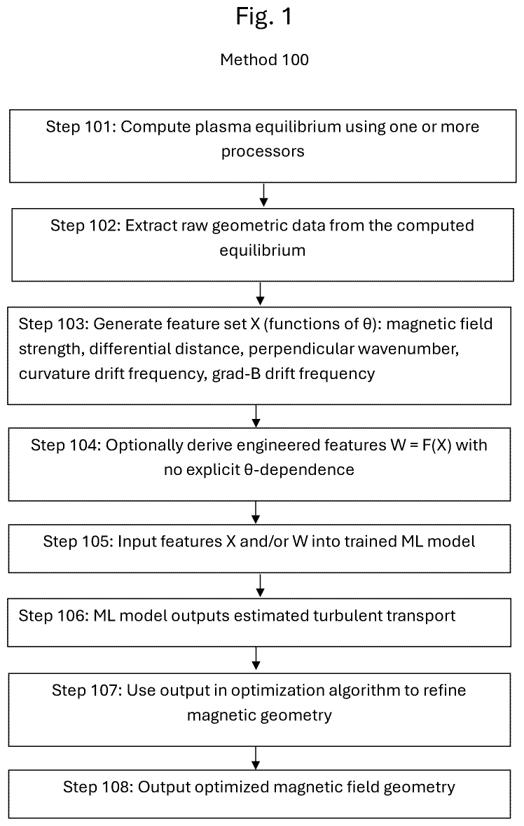

With reference to FIG. 1, a computer-implemented method 100 is described for designing a magnetic field geometry of a magnetically confined plasma using one-dimensional geometric features derived from a magnetic equilibrium.

The method begins by initiating the computation sequence. In Step 101, one or more processors compute an equilibrium configuration of a magnetically confined plasma. This equilibrium includes field line data and scalar quantities across magnetic flux surfaces. In Step 102, raw geometric data is extracted from the computed equilibrium. This data includes spatially dependent quantities along a magnetic field line, particularly in the ballooning representation common in gyrokinetic theory. In Step 103, a raw feature set X is generated. The set X comprises geometric functions of a coordinate θ along the field line and includes magnetic field strength, the differential distance along a field line, the magnitude of perpendicular wavenumber, the curvature drift frequency, and the grad-B drift frequency. These quantities represent the physical mechanisms by which geometry influences plasma turbulence. In Step 104, an optional set of engineered features W is computed from the raw features X. These engineered features are derived using functional mappings W=F(X), which preserve translational invariance by avoiding explicit dependence on 0. One example includes calculating the local trapped particle fraction. In Step 105, the features (X and/or W) are input into a machine learning (ML) model. The ML model has been previously trained using supervised learning on a dataset of gyrokinetic simulations. In Step 106, the ML model produces an output that estimates the turbulent transport associated with the given magnetic geometry. The transport estimate can include quantities such as normalized heat flux or diffusivity. In Step 107, this transport estimate is used within an optimization algorithm (OA) to refine the magnetic field geometry. The OA minimizes an objective function that includes the ML output as a target. In Step 108, the optimization procedure outputs a magnetic field geometry that is expected to result in reduced turbulent transport, thereby improving plasma confinement performance.

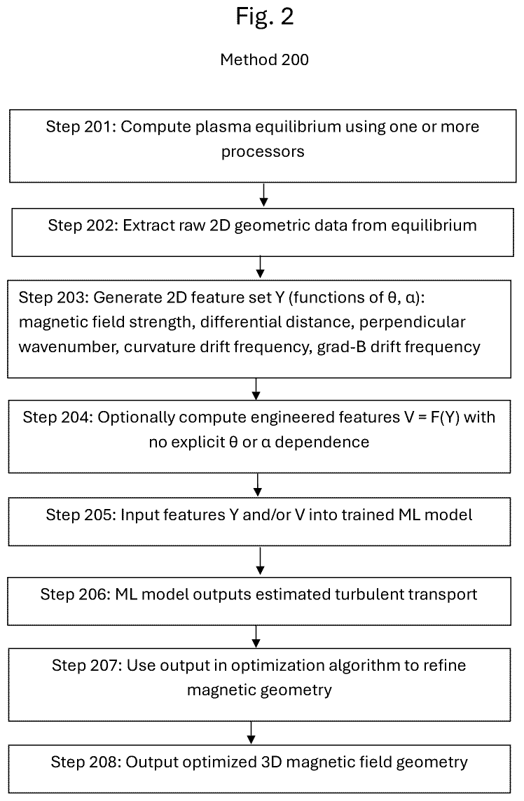

With reference to FIG. 2, a related method 200 generalizes the approach of FIG. 1 to magnetic field geometries defined by two angular coordinates on a flux surface: θ and α. The method begins by initiating the computation sequence. In Step 201, a plasma equilibrium is computed using one or more processors, as in the prior embodiment. In Step 202, raw two-dimensional geometric data is extracted. This data includes spatially resolved geometric functions defined across coordinates (θ, α) on a magnetic flux surface. In Step 203, a raw feature set Y is generated from the geometric data. The set Y includes the same physical quantities as in the 1D case (e.g., magnetic field strength, perpendicular wavenumber), but now as functions of both θ and α. In Step 204, a set of engineered features V may be computed from Y. These engineered features are also constructed to avoid explicit dependence on θ or α and may capture higher-level physical properties or symmetries of the configuration. In Step 205, the raw or engineered features are provided to a machine learning model that is configured to process two-dimensional inputs, such as a convolutional neural network. In Step 206, the ML model estimates the turbulent transport across the flux surface, based on its learned correlations from training data. In Step 207, the transport output is integrated into an optimization algorithm that iteratively adjusts the magnetic configuration. In Step 208, the method yields a refined three-dimensional magnetic field geometry optimized to suppress turbulent transport.

The methods described in FIGS. 1 and 2 may be implemented using a computing architecture including one or more physical processors configured to execute machine-readable instructions stored in memory. The memory stores: a pre-trained machine learning model capable of predicting gyrokinetic transport based on geometric inputs; software modules for extracting geometric features from magnetic equilibrium data; an optimization algorithm configured to adjust magnetic geometry parameters to minimize turbulent transport predictions. The system may include high-performance computing nodes or cloud-based environments capable of running gyrokinetic codes during training and rapid surrogate evaluations during optimization.

The predictive model that uses these geometric features could be a neural network. Neural networks have proven to be extremely successful with two-dimensional image data. The geometric features above are like one-dimensional image data. Based upon their success with image data, it is extremely likely that neural networks will be very successful with this type of data in the context of predictive models of gyrokinetic transport. (In the case of non-symmetric magnetic geometries with two coordinates θ, α′ or θ′, α′, the geometric features are like two-dimensional image data. We discuss this case below.) It is novel to use neural networks with such one-dimensional data for the purpose of constructing predictive models of the gyrokinetic equation for geometric optimization.

We note that after the provisional patent was filed by the present inventor on May 7, 2024, other workers in the field have recognized the analogies of the geometrical dependence of a form of gyrokinetic turbulence, namely ITG modes, with image recognition using neural networks, and also the advantage of the translational invariance property. Our filing on May 7, 2024, already described the translational invariance property and the advantages of using convolutional neural networks. Matt Landreman publicly disclosed this is October 2024 (https://terpconnect.umd.edu/˜mattland/assets/presentations/2025-02_Landreman_SSS-ML_turbulence_regression_v01.pdf) and February 2025 (https://arxiv.org/abs/2502.11657). This advantage was also noted in the abstract of Matt Landreman for the American Physical Society meeting, and the abstract was publicly published in September of 2024 (https://meetings.aps.org/Meeting/DPP24/Session/JP12.30). Other workers in the field have also publicly noted some advantages of using convolutional neural networks for ITG turbulence after our original filing (see Wan, May 2025, https://arxiv.org/html/2503.23676v1).

Other important engineered features can be derived from the raw features in X. For example, the trapped particle density is known to be an important aspect of many gyrokinetic instabilities. It can be derived from the B(θ). In simple geometries, the local trapped particle density (relative to the total density) is nₜ(θ)=(1−B(θ)/Bₘₐₓ)^{1/2}, where Bₘₐₓ is the maximum value B(θ) on the field line. (One can of course replace θ by θ′ in this.) This is an example of an engineered feature generated from the raw features. We denote the set of engineered features as W.

Other engineered features can be constructed as functionals F of the raw features, F(X). These engineered features will maintain the translational invariance property if the functional F does not contain any explicit dependence upon θ, but only depends upon θ via the X. Maintaining the translational invariance of engineered features is advantageous for the same reasons that it is advantageous for the raw features.

The previous discussion has been regarding features. An additional disclosure being made here is regarding desirable targets. These are appropriate for optimization of stellarator geometry, for various gyrokinetic transport properties. We now disclose a particular strategy for transport optimization with a particular property and possible specific functionals.

This property is the stabilization of ITG/TEM modes by density gradients, for some geometries. We will refer to this as Density Gradient Stabilization (DGS). This has been observed experimentally in various stellarator experiments. Gyrokinetic simulations (E.g., see Thienpondt. Et.al. Nucl. Fusion 65 (2025) 016062) shows that this can vary substantially in different stellarator geometries. Hence, it is desirable to optimize a geometry for this property.

We will also refer to this as a Constraint Based strategy (CB strategy). The physical principles are described in the patent “TECHNIQUES FOR ENHANCED CONFINEMENT IN MAGNETIC FUSION DEVICES” by M. Kotschenreuther, et. al., (hereafter referred to as the EC patent) and in the scientific paper https://arxiv.org/abs/2310.17107 by M. Kotschenreuther, et. al. Oct. 26, 2023 (hereafter referred to as the constraint paper), both of which are incorporated herein by reference in their entireties.

An important aspect of the CB strategy is to employ an appropriate magnetic geometry in combination with plasma density gradients. Such plasma density gradients can be created by particle sources of various kinds, as disclosed by the EC patent. The important characteristic of magnetic geometry that is needed for the CB strategy is that the instability eigenfunctions (or turbulent fluctuations) must not couple strongly to trapped electrons, as described in the EC patent and in the constraint paper. We will refer to this as the decoupling property. It is a property of solutions of the gyrokinetic equation.

Although the EC patent and the constraint paper describe physical principles, they do not describe algorithms that can be used to engineer the decoupling property into a magnetic configuration. Use of such algorithms would result in stellarators with superior confinement, which is highly desirable.

The present disclosure now turns to example target functions for the CB strategy, and predictive models to be used in the targets.

Since the electron dynamics are important for the decoupling property, gyrokinetic simulations must be performed including electron dynamics beyond the typical “adiabatic approximation” where the perturbed electron density δn is only proportional to eϕ/Tₑ, where Tₑ is the electron temperature. This approximation has usually been used in applications of ML to gyrokinetic transport up till now, including in the works cited above for Landreman and Wan. The need to go beyond the adiabatic electron strategy is described by Kotschenreuther in the constraint paper. Use of ML models for other instabilities also require non-adiabatic electrons to be simulated. Instabilities where this is necessary include KBM and MTM.

When the decoupling property is attained to a sufficient degree, the desirable DGS property is strong. As shown in the constraint paper, the property of decoupling is strongly dependent upon the magnetic field geometry. That is, the decoupling property is a consequence of the geometric features described above. The decoupling property does not hold for many magnetic geometries, it is much more strongly true in some geometries than in others. So, the magnetic geometry must be carefully tailored by the OA to create this property. Hence, the methods described above can be applied to the CB strategy: use the geometric features to develop a predictive model of low transport due to DGS.

An efficient strategy to engineer strong DGS requires a good mathematical target for the property, in addition to appropriate features as described above. The consequence of using such a target in an OA will be a stellarator device with greatly improved transport and confinement, which gives major improvements in performance of the device.

As described in the constraint paper, stability becomes manifest at a sufficiently large value of the normalized density gradient Fₚ (defined in that paper). And as shown there, there is considerable similarity in the Fₚ value for strong DGS across different geometries. Here we disclose that this allows an efficient procedure to optimize DGS.

The following procedure significantly reduces the dimensionality of the feature set that is needed to optimize DGS, as regards plasma parameters. Instead of a large number of density and temperature gradient values, it suffices to have only a very limited number of Fₚ values and a small number of representative temperature gradient values. It might only require a single temperature gradient (with ion temperature gradient scale length equal to the electron value) and a single Fₚ value. For cases with low impurities, Fₚ₀≈0.5 is appropriate. Other values of Fₚ₀ could also be used. The following definition of this is described in detail in the CB paper. One first defines a radial coordinate r, where r is usually taken as a function that is constant on a surface of constant flux. Then the equation that specifies Fₚ is the following (for a plasma species s, which could be a plasma ion species or the plasma electron species, and said species has a temperature T and a density n):

$${F}_{p} = [ ( 1 / n ) dn / dr ] / \{ [ ( 1 / n ) dn / dr ] + [ ( 1 / T ) dT / dr ] \} .$$

One could compute the nonlinear transport Q(Fₚ₀), which will be small if the decoupling property is present. A much less expensive procedure is to compute a linear approximation to the nonlinear diffusivity. These are often referred to in the art as “saturation rules”: means by which linear simulations can be used to estimate the nonlinear fluxes. A partial list of these references to saturation rules known in the art is as follows [F. Jenko et al 2005 Plasma Phys. Control. Fusion 47 B195, E.Fable et al 2008 Plasma Phys. Control. Fusion 50 115005, X. Lapillonne et al 2011 Plasma Phys. Control. Fusion 53 054011, N. Kumar et al 2021 Nucl. Fusion 61 036005, C. Bourdelle; X. Garbet, et. al., Phys. Plasmas 14, 112501 (2007), S. Parker et. al. Plasma 2023, 6(4), 611-622,https://theory.pppl.gov/news/seminars/12112019Kotschenreuther.pdf, see page 22]. A crucial quantity that appears in many of these rules is called Dₘᵢₓ.

Instead of the absolute heat flux Q or Dₘᵢₓ, one could choose a normalized metric for the decoupling property as follows. One could compute Q(Fₚ=Fₚ₀)/Q(Fₚ=0) or Dₘᵢₓ(Fₚ=Fₚ₀)/Dₘᵢₓ (Fₚ=0). Other denominators could be used for this, that is, Dₘᵢₓ (Fₚ=0) could be replaced by another quantity that is representative of Dₘᵢₓ for Fₚ=0, but could be advantageous in some way (e.g. easier to compute). Small values of such metrics imply that there is strong DGS and that the property of decoupling from trapped electrons is strongly present in the magnetic geometry.

In conclusion, a trained ML model such as is described above can be used in the target of an OA to design a stellarator where low gyrokinetic transport arises by strong DGS.

For all the ML models described above, there are potential difficulties due to the high dimensionality of the feature space. Although the disclosures above reduce this dimensionality considerably, it may still be true that the dimensionality is undesirably high. We can illustrate the problem using a few typical numbers.

It is typical to express the functions X by their values on grid points. A typical number of grid points for a gyrokinetic problem is in the hundreds or thousands. A neural network for such systems would easily have thousands or tens of thousands of fitting parameters. As a rule of thumb in data science, one desires at least ten data points per fitting parameter. Thus, a neural network would require tens of thousands to hundreds of thousands of data points, where here, each data point is a gyrokinetic run. While it is certainly possible to make hundreds of thousands of gyrokinetic simulations, this can be expensive. Also, the number of available equilibrium geometries might be considerably less than is needed for this many data points.

Even with voluminous data, ML models with many thousands of dimensions can be brittle, or be highly inaccurate in certain domains. Hence, as often arises in data science, it is often advantageous to be able to fit a predictive model with a much smaller number of data points.

For the class of the geometric features X, one advantageous means of doing this is to use functionals or integrals of the geometrical features above, where the functional depends upon a much lower number of fitting parameters than the number of grid points. The functional should preserve the important invariance property of the original gyrokinetic system. We show how to do this.

In one example, the target is an integral over a function of these geometrical features, where the integrals have a much smaller number of fitting parameters than the number of grid points. Such a target gives a large reduction in the dimensionality of the feature space, and hence a sharp reduction in the data requirements. The important translational invariance property can be maintained by employing functionals that have no explicit dependence upon θ, that is, where the only dependence upon θ is through the subset of geometrical functions X. Hence the X enters a target T₀ of the form:

$${T}_{0} = {C}_{0} + {\int }_{- ∞}^{∞} d θ {G}_{1} ( X , W ) \qquad eq ( 1 )$$

Clearly, this target is invariant to shifting all the geometric functions by any amount θ′, since the function G₁ has no explicit θ dependence. The function G₀ and C₀ may depend upon other relevant parameters with no θ dependence, e.g., they can depend upon plasma parameters that are a constant on a field line. Such parameters are well known in the art, and examples include, the equilibrium density or temperature, gradients of equilibrium density or temperature in flux coordinates, etc. These are often referred to as local scalar parameters in the art, and we will refer to them as such. We will denote any set of such local scaler parameters by S.

Hence, a desirable target would be:

$${T}_{0 B} = {C}_{0} + {\int }_{- ∞}^{∞} d θ {G}_{1} ( X , W , S ) \qquad eq ( 2 )$$

Where G₁ contains fitting parameters. This can obviously be generalized to a functional F₁ of the integral:

$${T}_{1} = {F}_{1} [ {\int }_{- ∞}^{∞} d θ {G}_{1} ( X , W , S ) ] \qquad eq ( 3 )$$

In practice, computer implemented methods adjust fitting parameters in F₁ and G₁ to minimize the error on a training dataset.

Eq(1) and eq(2) are but special cases of eq(3), which subsumes them.

Note that, as is conventional in the art of numerical integration in practical cases, the integration bounds of infinity can be replaced by some large but finite θ value that approximates infinity.

Other functional forms that have the translational invariance property are a maximum over θ of a function of X and S.

$${T}_{2} = {max}_{θ} {G}_{2} ( X , W , S ) \qquad eq ( 4 )$$

The function G₂ has no explicit θ dependence but may depend upon local scalar parameters.

Clearly, this maximum is also invariant to shifting all the geometric functions by any amount θ′. In practice, computer implemented methods adjust fitting parameters in G₂ to minimize the error on a training dataset.

An additional class of ML models can be obtained from the solution of a system of differential or integro-differential equations. We write a system [symbol] of such equations in the variable θ for quantities ϕᵢ. The system contains some members of the set X and W, and also a set of fitting parameters p.

$${S}_{3} ( {ϕ}_{i} , θ , X , W , S , p ) = 0 \qquad eq ( 5 )$$

Note that this will have the invariance property as long as: 1) the system [symbol] has no explicit θ dependence other than differential operators dⁿ/dθⁿ and integrals ∫dθ, and depends upon the geometric functions in X and W, so it has θ dependence only through them; and 2) the boundary conditions are to vanish at infinity. (As is conventional in numerical analysis, boundary values at infinity can be approximated by boundary values at a large value to approximate infinity).

The target T₃ is a functional of the solutions ϕᵢ, T₃=F₃[ϕᵢ, q], where q are potentially additional fitting parameters to p in eq(5). In practice, computer implemented methods adjust both p and q to minimize the error on a training dataset.

A particular type of differential or integro-differential system is an eigenvalue problem with specified boundary conditions. Denote the eigenvalue as λ, and it can be either a real number or a complex number. The eigensystem is:

$${S}_{4} ( {ϕ}_{i} , λ , θ , X , W , S , p ) = 0 \qquad eq ( 6 )$$

The target can be T₄=F₄[λ, ϕᵢ, q], where q are potentially additional fitting parameters to the fitting parameters p in eq(6). In practice, computer implemented methods adjust both p and q to minimize the error on a training dataset.

Finally, partial differential equations are another type of differential equation. For example:

$$\partial {ϕ}_{i} / \partial t = {S}_{5} ( {ϕ}_{i} , θ , X , W , S , p ) \qquad eq ( 7 )$$

The target can be T₅=F₅[ϕᵢ, q], where F₅ can include additional fitting parameters q to the fitting parameters p in eq(7). In practice, computer implemented methods adjust both p and q to minimize the error on a training dataset.

We note that fluid equations have been used to describe instabilities and turbulence in OA. For example, this has been done using the GX code, as described in https://arxiv.org/html/2310.18842v2. These fluid equations are advanced in time to predict the transport. The form of the GX equations can be considered an example of the eq(7) above, but there is a crucial difference from this patent. All the parameters in the GX equations are specified: none are determined by an ML procedure to minimize differences from a set of more accurate gyrokinetic simulations.

More accurate gyrokinetic simulations are more expensive. For example, more expansion basis functions are used to describe the velocity space of the gyrokinetic simulation, which increases the cost. Hence, it is advantageous to use much less expensive simulations with fewer equations in an OA. Accuracy is improved by adding fitting parameters to the equation, and using a ML procedure to minimize the differences from more accurate and expensive simulations.

Fluctuation induced transport is often considered as averaged over a flux surface. Such a surface has a constant value of the magnetic flux; this is understood by those skilled in the art. Each field line on a flux surface could have a different functional dependence of the functions in X, as is well known. In other words: a flux surface is specified by two angles, one of which is θand we will call the other α′. As is often done in the field, one can consider the flux surface properties to be an appropriate sum of the transport on field lines with various angles α′, where each field line has one-dimensional functions only in terms of θ, as above.

However, it is also known in the field that, sometimes, instability properties depend upon the variations of the geometry with a′ in a flux surface. Then, the considerations in this disclosure carry over by considering the geometric features to be two dimensional (i.e. ω_{κ}(θ, α), ω_{B}(θ, α), k_{⊥}(θ, α), [symbol] (θ, α) and B(θ, α)).

In other words, we can define the set Y of 2D features:
Y⊆{ω_{κ}(θ, α), ω_{B}(θ, α), k_{⊥}(θ, α), [symbol] (θ, α) and B(θ, α)}

These features can be used, instead of one-dimensional features, in each of the ML models described above.

The descriptions above for X can be generalized by replacing the one-dimensional features X with the two-dimensional features Y.

So eq(3) generalizes to:

$${T}_{6} = {F}_{6} [ {\int }_{- ∞}^{∞} d θ d α {G}_{6} ( Y , W , S ) ] \qquad eq ( 8 )$$

In practice, computer implemented methods adjust fitting parameters in F₆ and G₆ to minimize the error on a training dataset.

Equation (4) generalizes to:

$${T}_{7} = {max}_{θ , α} {G}_{7} ( Y , W , S ) \qquad eq ( 9 )$$

In practice, computer implemented methods adjust fitting parameters in F₇ and G₇ to minimize the error on a training dataset.

Equation (5) generalizes to:

$${𝒮}_{8} ( {ϕ}_{i} , θ , α , Y , W , S , p ) = 0 \qquad eq ( 10 )$$

The target T₈ is a functional of the solutions ϕᵢ, T₈=F₈[ϕᵢ, q], where q are potentially additional fitting parameters to p in eq(10). In practice, computer implemented methods adjust both p and q to minimize the error on a training dataset.

Equation (6) generalizes to:

$${𝒮}_{9} ( {ϕ}_{i} , λ , θ , a , Y , W , S , p ) = 0 \qquad eq ( 11 )$$

The target can be T₉=F₉[λ, ϕᵢ, q], where q are potentially additional fitting parameters to the fitting parameters p in eq(11). In practice, computer implemented methods adjust both p and q to minimize the error on a training dataset.

Equation (7) generalizes to:

$$\partial {ϕ}_{i} / \partial t = {𝒮}_{10} ( ϕ , θ , α , Y , W , S , p ) \qquad eq ( 12 )$$

The target can be T₁₀=F₁₀[ϕᵢ, q], where F₁₀ can include additional fitting parameters q to the fitting parameters p in eq(12). In practice, computer implemented methods adjust both p and q to minimize the error on a training dataset.

Finally, while the present invention has been described above with reference to various exemplary embodiments, many changes, combinations and modifications may be made to the exemplary embodiments without departing from the scope of the present invention. For example, the various mathematical models may be implemented in alternative ways. These alternatives can be suitably selected depending upon the particular application or in consideration of any number of factors. In addition, the techniques described herein may be extended or modified for use with other types of fusion devices. These and other changes or modifications are intended to be included within the scope of the present invention.

What is claimed is:

1. A computer implemented method for designing a magnetic field geometry of a confined plasma to optimize the losses of energy or particles from plasma turbulence, the method comprising:
(a) computing an equilibria of the confined plasma by one or more processors,
(b) obtaining, by the one or more processors, raw data from the computed equilibria;
(c) generating, by the one or more processors, a raw feature set comprising geometric functions used in a gyrokinetic equation in ballooning representation, with a coordinate θ that specifies a position along a field line, and a subset X of the set of geometric functions of θ for a magnetic field strength, a differential distance along a field line, a perpendicular wavelength, a curvature drift frequency, and a grad-B drift frequency;
(d) generating, based on a machine-learning (“ML”) model, an estimate of turbulent transport, wherein the feature set of the ML model includes at least one of:
(i) the raw features in X
(ii) a set of engineered features W derived from the raw features, wherein the functional relationship between W and X, W=F(X) does not contain an explicit dependence upon θ;
(f) the ML model having been trained, prior to being used for optimizing the magnetic field, using computer-implemented means to minimize a loss function for a difference between the ML model estimate of the transport and other estimates of the transport computed by gyrokinetic simulations on a dataset of magnetic field geometries.

2. The method of claim 1, wherein the ML model incorporates the property of translational invariance of the turbulent transport if all the geometric functions in the coordinate are shifted in θ by the same amount.

3. The method of claim 1, wherein the ML model is a convolutional neural network in the coordinate θ and at least one of the members of set X of raw features and engineered features derived from raw features in X.

4. The method of claim 1, wherein the ML model M(X,W) is expressed as
$$M ( X , W ) = G [ \int d θ {F}_{i} ( X , W ) ]$$
wherein (a) Fᵢ denotes a sequence of one or more functionals F₁, F₂, . . . (collectively Fᵢ) and (b) G is another functional applied the integral of the Fᵢ, and (c) at least one fitting parameter contained in any of the functionals of Fi or in the functional G is adjusted by computer implemented methods to minimize the loss function.

5. The method of claim 1, wherein the ML model M(X,W) is expressed as
$$M ( X , W ) = {max}_{θ} F ( X , W )$$
and wherein, in the functional F, at least one fitting parameter is adjusted by computer implemented methods to minimize the loss function.

6. The method of claim 1, wherein the ML model M(X,W) is implemented by first solving a system of at least one of differential equations and integro-differential equations in θ for quantities ϕᵢ, where the system has a set of fitting parameters p
$$𝒮 ( {ϕ}_{i} , θ , X , W , S , p ) = 0 \qquad eq ( 5 )$$
and then computing M(X,W)=G(ϕᵢ, q), wherein at least one of the set of p and q is adjusted by computer implemented methods to minimize the loss function.

7. The method of claim 1, wherein the ML model M(X,W) is implemented by first solving a system of at least one of differential equations and integro-differential equations for quantities ϕᵢ with an eigenvalue λ, where the system has a set of fitting parameters p
$$𝒮 ( {ϕ}_{i} , λ , θ , X , W , p ) = 0$$
and using the solution of this to compute M(X, W)=G(ϕᵢ, λ, q), and wherein at least one of the set of p and q is adjusted by computer implemented methods to minimize the loss function.

8. The method of claim 1, wherein the ML model M(X,W) is implemented by a first solution of a system of at least one of partial differential equations and integro-differential equations for quantities ϕᵢ, where ∂ϕᵢ/∂t is specified as at least one of a differential operator and an integro-differential operator [symbol] with a set of fitting parameters p, where
$$\partial {ϕ}_{i} / \partial t = 𝒮 ( {ϕ}_{i} , θ , X , W , p )$$
and using this solution to compute M(X,W)=G(ϕᵢ, λ, q), wherein at least one of the set of p and q is adjusted by computer implemented methods to minimize the loss function.

9. A computer-implemented method of designing a magnetic field geometry of a magnetically confined plasma for optimizing the losses of energy or particles from plasma turbulence, the method comprising:
(a) computing an equilibria of the confined plasma by one or more processors;
(b) obtaining, by the one or more processors, raw data from the computed equilibria;
(c) generating, by the one or more processors, a raw feature set comprising geometric functions used in a gyrokinetic equation in ballooning representation, with coordinates θ and α that specify positions along a surface, and a subset Y of the set of functions of (θ, α) for a magnetic field strength, a differential distance along a field line, a perpendicular wavelength, a curvature drift frequency, and a grad-B drift frequency;
(d) wherein a ML model gives an estimate of the turbulent transport
(e) wherein the feature set of the ML model includes at least one of
(i) the raw features in subset Y;
(ii) a set of engineered features V derived from the raw features in subset Y, wherein the functional relationship between V and Y, V=F(Y) does not contain an explicit dependence upon θ or α;
(f) said machine learning model having been trained, prior to being used for optimizing the magnetic field, using computer-implemented means to minimize a loss function for a difference between a ML model estimate of the transport and other estimates of the transport computed by gyrokinetic simulations on a dataset of magnetic field geometries.

10. The method of claim 9, wherein the ML model incorporates a property of translational invariance of the turbulent transport if all the geometric functions in the coordinate are either shifted in θ by the same amount or shifted by a by the same amount.

11. The method of claim 9 wherein the ML model is a convolutional neural network in the coordinates θ and a and at least one of the members of subset Y of the raw features and of the engineered features is derived from the raw features in V.

12. The method of claim 9, wherein the ML model M(Y,V) is expressed as
$$M ( Y , V ) = G [ \int d θ {F}_{i} ( Y , V ) ]$$
wherein (a) Fᵢ denotes a sequence of one or more functionals F₁, F₂, . . . (collectively Fᵢ) and (b) G is another functional applied to the integral of the Fᵢ, and (c) at least one fitting parameter contained in any of the functionals of Fᵢ or in the functional G is adjusted by computer implemented methods to minimize the loss function.

13. The method of claim 9, wherein the ML model M(Y,V) is expressed as
$$M ( Y , V ) = {max}_{θ , α} F ( Y , V )$$
and wherein, in the functional F, at least one fitting parameter is adjusted by computer implemented methods to minimize the loss function.

14. The method of claim 9, wherein the ML model M(Y,V) is implemented by first solving a system of at least one of differential equations and integro-differential equations in θ and α for quantities ϕᵢ, where the system has a set of fitting parameters p
$$𝒮 ( {ϕ}_{i} , θ , α , Y , V , p ) = 0 \qquad eq ( 5 )$$
and using the solution of this to compute M(Y,V)=G(ϕᵢ, q), wherein at least one of the set of p and q is adjusted by computer implemented methods to minimize the loss function.

15. The method of claim 9, wherein the ML model M(Y,V) is implemented by first solving a system of at least one of differential equations and integro-differential equations in θ and α for quantities ϕᵢ with an eigenvalue λ, where the system has a set of fitting parameters p
$$𝒮 ( {ϕ}_{i} , λ , θ , α , Y , V , p ) = 0 \qquad eq ( 6 )$$
and using the solution to compute M(Y,V)=G(ϕᵢ, λ, q), wherein at least one of the set of p and q is adjusted by computer implemented methods to minimize the loss function.

16. The method of claim 9, wherein the ML model M(Y,V) is implemented by first solving a system of differential equations or partial differential equations for quantities ϕᵢ, giving derivatives ∂ϕᵢ/∂t as functions of at least one of a differential operator and integro-differential operator [symbol] with a set of fitting parameters p
$$\partial {ϕ}_{i} / \partial t = 𝒮 ( {ϕ}_{i} , θ , α , Y , V , p )$$
and using this to compute M(Y,V)=G(ϕᵢ, λ, q), wherein at least one of the set of p and q constitutes an engineered feature set used to train the ML model.

17. The method of claim 1, wherein gyrokinetic simulations used in the loss function do not use adiabatic electrons.

18. The method of claim 9, wherein gyrokinetic simulations used in the loss function do not use adiabatic electrons.

19. The method of claim 1, wherein the loss function is obtained by gyrokinetic simulations with less than ten values of the parameter Fₚ, wherein Fₚ is defined by first defining a radial coordinate r, and wherein a plasma species has a temperature T and a density n, and the value of Fₚ is given by Fₚ=[(1/n)dn/dr]/{[1/n)dn/dr]+[(1/T)dT/dr]}.

20. The method of claim 9, wherein the loss function is obtained by gyrokinetic simulations with less than ten values of the parameter Fₚ, wherein Fₚ is defined by first defining a radial coordinate r, and wherein a plasma species has a temperature T and a density n, and the value of Fₚ is given by Fₚ=[(1/n)dn/dr]/{[(1/n)dn/dr]+[(1/T)dT/dr]}.
